(19) United States
(12) Patent Application Publication
(10) Pub. No.: US 2004/0171274 A1
(43) Pub. Date: Sep. 2, 2004

(54) Method for formation of hardmask elements during a semiconductor device fabrication process

(76) Inventors: Haoren Zhuang, Tokyo-to (JP); Ulrich Egger, Kanagawa-ken (JP); Uwe Wellhausen, Kanagawa-ken (JP); Rainer Bruchhaus, Kanagawa-ken (JP); Karl Hornik, Kanagawa-ken (JP); Jingyu Lian, Tokyo-to (JP); Gerhard Beitel, Kanagawa-ken (JP); Kazuhiro Tomioka, Kanagawa-ken (JP); Katsuki Natori, Kanagawa-ken (JP)

Correspondence Address: FISH & RICHARDSON, PC, 12390 EL CAMINO REAL, SAN DIEGO, CA, 92130-2081, US

(21) Appl. No.: 10/377,293

(22) Filed: Feb. 27, 2003

(51) Int. Cl. H01L 21/302; H01L 21/00; H01L 21/461

(52) U.S. Cl. 438/722

(57) ABSTRACT

In semiconductor device fabrication processes which include the formation of hardmask elements 17 including Al₂O₂, unwanted Al₂O₃ is left between the hardmask elements 17. The unwanted Al₂O₃ includes a layer 9 of Al₂O₃which is not homogenous across the surface of the structure 3 it overlies, and Al₂O₃ deposits on the sides of the hardmask elements 17. A method is proposed in which any such unwanted Al₂O₃ between the hardmask elements 17 is removed by a wet etching step in which the unwanted Al₂O₃ is exposed to an etchant liquid which etches the Al₂O₃ at a faster rate than other portions of the structure. This step allows the unwanted Al₂O₃ to be removed substantially completely without causing significant detriment to those other portions of the structure. Subsequently, an RIE etching step can be performed using the hardmask elements 17 as a mask, without the unwanted Al₂O₃ obstructing the RIE etching step.

### Field of the Invention

The present invention relates to method of removing alumina (Al₂O₃) from hardmask elements formed during a semiconductor fabrication process, and in particular a process for forming a semiconductor device including one or more Ferroelectric capacitors.

### BACKGROUND OF INVENTION

Known multilayer FeRAM (Ferroelectric Random Access Memory) and DRAM devices include ferrocapacitors comprising a top electrode layer and a bottom electrode layer separated by a ferroelectric layer. The bottom electrode is connected to lower layers of the devices using polysilicon contact plugs or Tungsten (W) plugs. The ferroelectric materials in FeRAMs and high K materials in DRAM are generally crystallized at a high temperature (600 C or above) in ambient oxygen. During this process, a barrier is required to prevent oxygen diffusion from the ferroelectric capacitor to the contact plug. An Ir (Iridium) based barrier is a good material to efficiently block this oxygen diffusion. Subsequently, the barrier layer is removed by etching using respective hardmask elements to cover each of the ferrocapactitors. Typically, the hardmask layer may be TEOS, and an alumina layer may be provided as an interlayer between the bottom electrode and the hardmask.

FIG. 1(a) to 1(b) shows a known process for forming hard masks. The initial structure is as shown in FIG. 1(a). It includes a layer 1 of TEOS (Tetraethyl Orthosilicate), which may overlie other layers including electronic components. Above the TEOS layer 1 is a barrier layer 3 which includes a lower barrier layer 5 of Ir (or Ir and lrO2) and thickness 120 nm having the function of stopping oxygen damage to the plugs, and an upper barrier layer 7 of Pt and thickness 10 nm. Above the barrier layer 3 is a layer 9 of Al₂O₃, which may have a thickness of 20 nm. Above the alumina layer 9 is an dTEOS (dilute TEOS) layer 11 of thickness 100 nm. The dTEOS layer 11 is covered with a patterned mask 13.

During a subsequent RIE (reactive ion etching) step referred to as “ hard mask opening”, the structure is transformed into that shown in FIG. 1(b), mask elements 13 have been removed, and the dTEOS layer 11 and Al₂O₃ layer 9 have been partially removed. The remaining portions of the layer 11 and the Al₂O₃ portions beneath them constitute the hard mask elements 17. After the mask opening step, part of the etched Al₂O₃ remains on the sidewalls of the hard mask elements 17 (these deposits are referred to as “fences”), and part of the Al₂O₃ is on top of the etched layers.

Note that the exposed parts of the Al₂O₃ layer 9 do not have a uniform thickness. This is because the thickness of the dTEOS layer 11, and in particular the effectiveness of the RIE machine, and are both inhomogeneous. In particular, the RIE machine may apply an average over-etch of 5%, which is an over-etch of 0% in the area A and 10% in the area B. Assuming that the thickness of the hard mask is 1000 nm, and the typical selectivity of Al₂O₃ to dTEOS is 10 (i.e. the rate of etching of dTEOS is ten times as fast as that of Al₂O₃). This will mean that an additional Al₂O₃ thickness of 10 nm is etched in the area B as compared to the area A. In an inner area A of the structure, the thickness of the Al₂O₃ layer 9 (in portions not covered by the remaining portions of the dTEOS layer 11) is 20 nm. At the outer area B of the structure, the thickness of the uncovered portions of the Al₂O₃ layer 9 is 10 nm. The amount of fences also depends upon the position on the surface, so that typically the level of fences is high in the edge area B, whereas there are no fences in the area A.

At this stage BE (bottom electrode) RIE is carried out, using the hardmasks formed the previous step. FIG. 1(c) shows the structure after 3 minutes of BE etching at an etch rate of 5 nm/min. By this time, the thickness of the uncovered Al₂O₃ in the area A is 5 nm. However, in the area B all the A1₂0₃ has already been removed, and the etching of the lower barrier layer 5 has already begun, By the time that the RIE has been completed, the structure is as shown in FIG. 1(d).

One function of the Al₂O₃ layer 9 is to prevent the RIE machine being contaminated by the Pt or Ir during the hard mask opening process (i.e. between FIGS. 1(a) and 1(b)). Another function is to guarantee that none of the dTEOS layer 11 remains at the opened positions after the hard mask opening step. This is because the etching rate of dTEOS is much higher than that of Al₂O₃.

However, the inhomogeneity in the Al₂O₃ causes the following three problems in the BE RIE process. The first is that the fence situation is difficult to control. The fences are partially controlled by the shape of the hard mask. However, the hard mask shape is controlled by the Al₂O₃ fences, because of the low etching rate of the Al₂O₃ In area B, due to the fences, 50% of the Al₂O₃ is etched by the oxide RIE machine (i.e. the etching of the TEOS and Al₂O₃, as shown in FIG. 1(b)), and 50% of the Al₂O₃ is etched by the metal RIE machine (etching of the remaining Al₂O₃, Pt, Ir, TEOS, as shown in FIGS. 1(c) and (d)). By contrast, in the area A the Al₂O₃ is 100% etched by the metal etching machine. Thus, due to the fences, the BE etching is not uniform.

The second problem is that the inhomogeneity makes the BE etching hard to control. During the BE etching the etch rate in the area B (where Pt and Ir is being etched) will be 50 nm/min, but the etch rate in area A (where Al₂O₃ is being etched) is 5 nm/min. Therefore, the location B will start to etch Pt two minutes earlier than area A. This means that the endpoint of the etching is not clear, so that there may be over-etching of the TEOS layer 1. It is known that over-etching may cause a peeling problem.

The third problem is that the inhomogenity in the Al₂O₃ thickness increases the total time required by the etching process to ensure that the whole of the desired Al₂O₃ has been removed. For example, in the case of a structure with a thickness of Ir of 120 nm, the total etching time will be 7 mins. Of this, 4 mins is for the Al₂O_{3,} 3 mins is for the Ir, and 2 mins is over-etching.

### SUMMARY OF THE INVENTION

The present inventors have appreciated that it would be advantageous to remove the Al₂O₃ between the mask elements prior to the BE etching, so as to remove its inhomogeneity,

The present invention aims to provide a method for removing unwanted Al₂O₃ as part of a method of formation of hardmask elements in a semiconductor device fabrication process.

In general terms, the invention proposes that in a wafer formed with a hardmask elements including Al₂O₃ and unwanted Al₂O₃ between the elements of the hardmask, a wet etching step should be performed. By “wet etching” is meant a process of etching in which the Al₂O₃ is removed by exposure to an etchant liquid. The etchant liquid may be such that the Al₂O₃ is etched at a faster rate than other portions of the structure, so that the unwanted Al₂O₃ can be removed without causing significant detriment to those other portions of the structure

More specifically, the invention proposes that in a semiconductor device fabrication process, a method for forming on a structure a hardmask comprising Al₂O₃ should comprise:

forming a layer comprising Al₂O₃;

forming a mask layer over the layer comprising Al₂O₃;

etching portions of the layer comprising Al₂O₃ which are exposed by the mask layer, to form hardmask elements; and

performing wet etching to remove Al₂O₃ between the hardmask elements.

### BRIEF DESCRIPTION OF THE FIGURES

Preferred features of the invention will now be described, for the sake of illustration only, with reference to the following figures in which:

FIG. 1, which is composed of FIGS. 1(a) to 1(d), shows the steps in a known process of forming a hard mark, and using that harkmask to perform BE etching;

FIG. 2, which is composed of FIGS. 2(a) to 2(d), shows a method according to the invention; and

FIG. 3 shows electron microscope photographs taken during the process of FIG. 2.

### DETAILED DESCRIPTION OF THE EMBODIMENTS

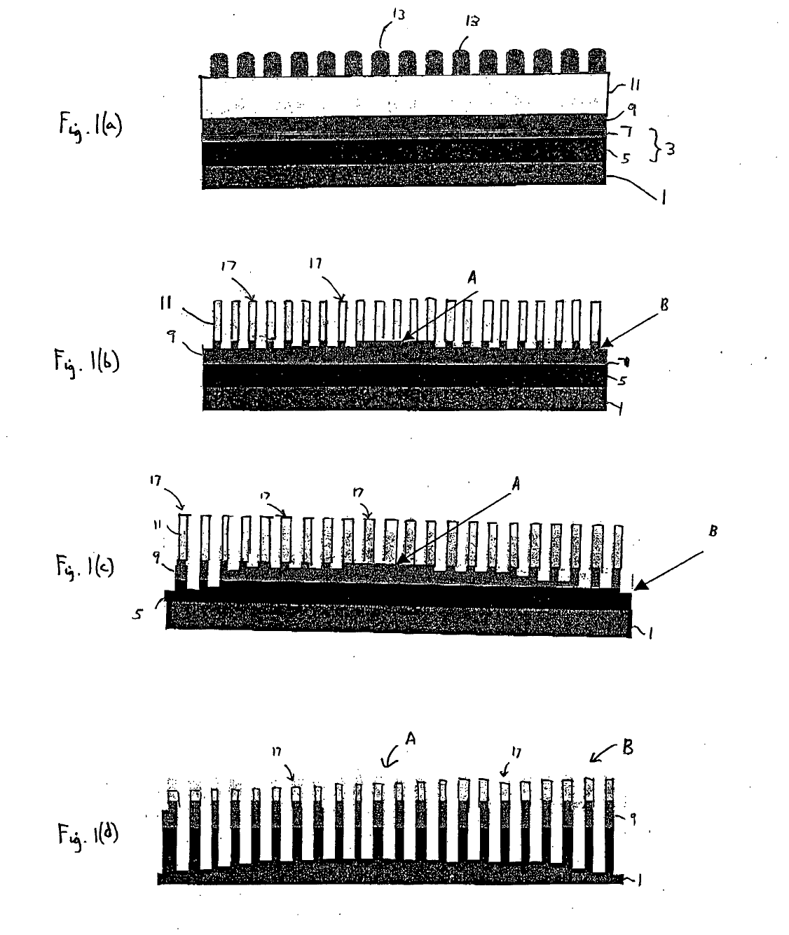

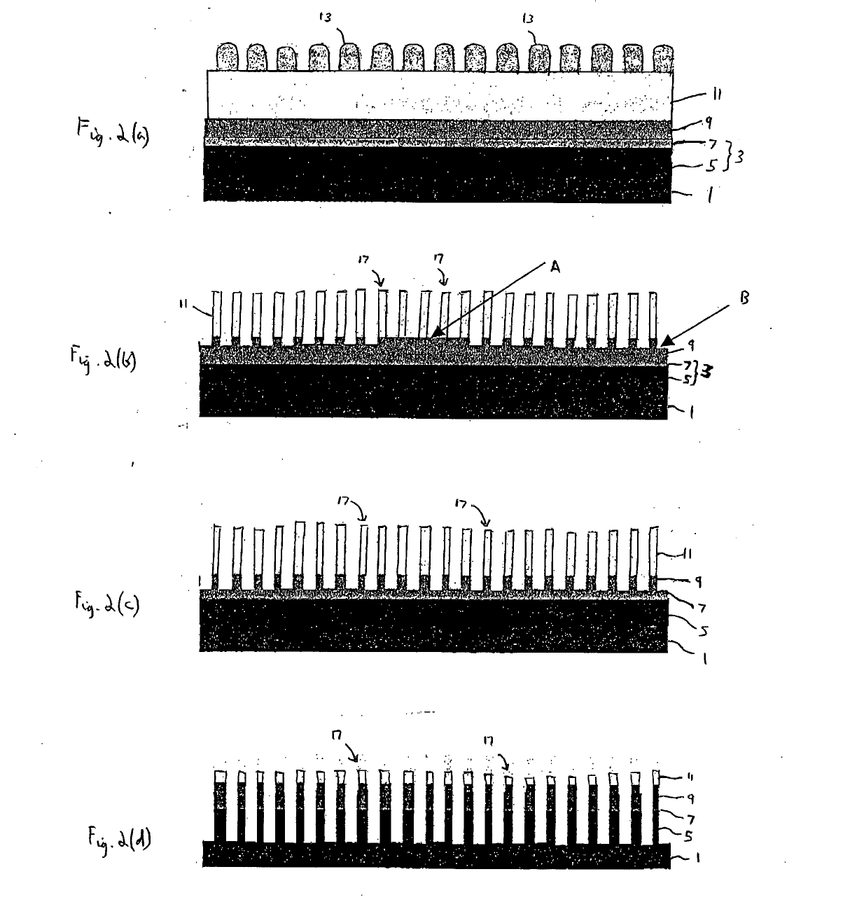

Referring firstly to FIG. 2(a), the initial structure used in the embodiment of the invention may be exactly as shown in FIG. 1(a) and as described above. Portions of the structure corresponding to those of FIG. 1(a) are given identical reference numerals. That is, the structure shown in FIG. 2(a) comprises a layer 1 of TEOS (Tetraethyl Orthosilicate), which may overlie other layers including electronic components. Above the TEOS layer 1 is a barrier layer 3, which includes a lower barrier layer 5 of Ir and thickness 120 nm and an upper barrier layer 7 of Pt and thickness 1 On. Above the barrier layer 3 are bottom electrode, ferroelelectric and top electrode layers (not shown) and then a layer 9 of Al₂O₃, which may have a thickness of 20 nm. Above the alumina layer 9 IS an dTEOS layer 11 of thickness 100 nm. The dTEOS layer 11 is covered with a patterned mask 13.

Likewise, the first step of the hardmask forming method is as in the known method described above, to give a structure shown in FIG. 2(b) which is identical to that of FIG. 1(b), and in which the mask elements 13 have been removed, and the dTEOS layer 11 and Al₂O₃ layer 9 have been. partially removed. The remaining portions of the layer 11 and the Al₂O₃ portions beneath them constitute the hard mask elements 17. Part of the etched Al₂O₃ remains as fences on the sidewalls of the hard mask, and part of the Al₂O₃ is on top of the etched layers.

At this point, however, the method according to the invention proposes that the top surface of the structure shown in FIG. 1(b) should be treated with a wet etching step using an etchant liquid. This may be a spin etching technique, i.e. one in which the wafer is rotated about an axis perpendicular to its surface (i.e. a vertical axis as shown in FIG. 2(b)) while the etchant liquid is applied to the surface to be etched. The etchant liquid may include hydrofluoric acid (HF), and more specifically may be dilute hydrofluoric acid (DHF). For example, using an HF concentration of under 5% in the case of the dimensions of the structure given above and an Al₂O₃ layer 9 which was formed by room temperature sputtering using O₂ or Ar and an Al₂O₃ target (although this may alternatively be formed by atomic layer deposition, ALD), we have found that spin etching for 1 min using a 1% HF solution is able to substantially completely remove the Al₂O₃ at the open areas (i.e. apart from the Al₂O₃ which is part of the hardmnask elements 17), while removing only a small amount of dTEOS. Thus, the method forms the structure shown in FIG. 2(c).

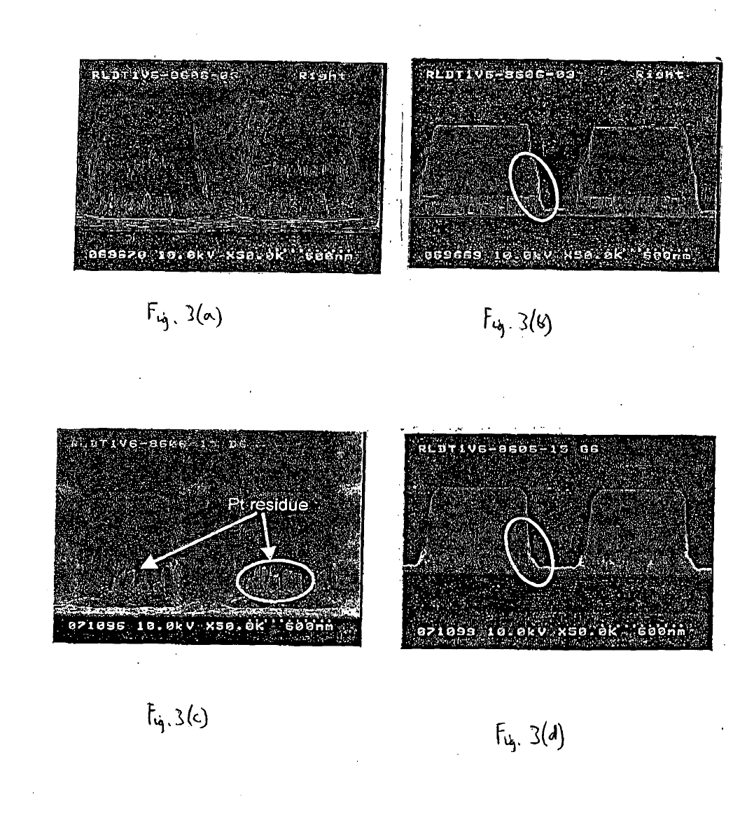

This is illustrated in FIG. 3, which shows as FIGS. 3(a) and 3(b) two electron microscope views of a structure shown in FIG. 2(b) before the wet-eching process is carried out. FIGS. 3(c) and 3(d) are corresponding views of a structure as shown in FIG. 2(c) after the wet etching is carried out for 1 min using 1% HF. As can be seen, the Al₂O₃ fences (shown in the oval on FIG. 3(b)) are removed completely in FIG. 3(d).

Once the hardmask has been completed as shown in FIG. 2(c), the structure shown in FIG. 2(d) can then be obtained by BE etching using conventional techniques. For example, as in the conventional method, the hardmask may be used in a BE RIE etching process, to give the result shown in FIG. 2(d), in which the Pt and Ir layers 5, 7 and the upper portions of the TEOS layer 1 are removed except under the hardmask elements The upper surface of the TEOS layer 1 can be substantially even across the entire surface of the wafer. Note that, although not shown in FIGS. 2(a) to 2(d), the masking elements 17 cover respective ferroelectric capacitors above the barrier layer 3. In this case, the TEOS layer 1 and the structure beneath it may include lower layers including electronic components electrically connected to the ferroelectric capacitors using (polysilicon) contact plugs.

Although only a single embodiment of the invention has been described in detail, various variations are possible within the scope of the invention as will be clear to a skilled reader. In particular, the etchant liquid used may be different from the DHF described above. Also, just as many methods are known which employ hardmask etching techniques in the fabrication of semiconductor devices, so the embodiments of the present invention exist in which a liquid etching step is added to the known techniques prior to a BE etching process using a hardmask.

1. In a semiconductor device fabrication process, a method for forming on a structure a hardmask comprising Al₂O₃ , the method comprising:
forming a layer comprising Al₂O₃;
forming a mask layer over the layer comprising Al₂O₃:
etching portions of the layer comprising Al₂O₃ which are exposed by the mask layer, to form hardmask elements; and
performing wet etching to remove Al₂0₃ between the hardmask elements.

2. A method according to claim 1 in which the wet etching is performed by spin wet etching.

3. A method according to claim 1 in which the wet etching is performed using dilute hydrofluoric acid.

4. A method according to claim 1 in which the layer comprising Al₂O₃ is formed by sputtering using an Al₂O₃ target or by atomic layer deposition.

5. A method for manufacturing a ferroelectric capacitor comprising the steps of:
forming a substructure of the capacitor having a contact plug passing therethrough for electrically connecting a bottom electrode of the capacitor to an underlying active layer;
depositing over the substructure the bottom electrode including a barrier layer intermediate therebetween having a composition including Iridium;
depositing over the bottom electrode a ferroelectric layer such that the diffusion of oxygen from the ferroelectric layer to the contact plug is inhibited by the intermediate barrier layer;
depositing over the ferroelectric layer a top electrode;
forming a hardmask over the top electrode by a method according to claim 1; and
etching portions of the top electrode, ferroelectric layer, bottom electrode and barrier layer not covered by the hardmask.
